(19) United States
(12) Patent Application Publication
(10) Pub. No.: US 2018/0046051 A1
(43) Pub. Date: Feb. 15, 2018

(54) ARRAY SUBSTRATES AND THE MANUFACTURING METHODS THEREOF

(71) Applicant: Shenzhen China Star Optoelectronics Technology Co., Ltd., Shenzhen, Guangdong (CN)

(72) Inventor: Xiangwei JIANG, Shenzhen, Guangdong (CN)

(73) Assignee: Shenzhen China Star Optoelectronics Technology Co. , Ltd., Shenzhen, Guangdong (CN)

(21) Appl. No.: 15/117,514

(22) PCT Filed: May 26, 2016
(86) PCT No.: PCT/CN2016/083531

§ 371 Date: Aug. 9, 2016

(30) Foreign Application Priority Data
Feb. 4, 2016 (CN) 201610079239.1

(51) Int. Cl. G02F 1/1362; G02F 1/1343; H01L 27/12; G02F 1/1368

(52) U.S. Cl. CPC G02F 1/136286; G02F 1/1368; G02F 1/13439; G02F 1/136227; H01L 27/1255; G02F 2201/121; G02F 2201/123; G02F 2203/01

(57) ABSTRACT

An array substrate includes a transparent substrate, at least one gate line, at least one data line, and at least one storage electrode line arranged on the transparent substrate, and at least one switch component arranged at an intersection of the gate line and the data line. The gate line and the data line are insulated from each other to define a pixel area, and the storage electrode line is arranged within the pixel area. The control end and the input end of the switch component respectively connect to the gate line and the data line, and the output end of the switch component extends into the pixel area so as to be opposite to the storage electrode line, and the output end and the storage electrode line are insulated from each other.

### BACKGROUND OF THE INVENTION

### 1. Field of the Invention

The present disclosure relates to liquid crystal display technology, and more particularly to an array substrate and the manufacturing method thereof.

### 2. Discussion of the Related Art

With the development of optoelectronics and the semiconductor technology, the flat panel displays have also been widely developed. Among the flat panel displays, the liquid crystal displays (LCDs) are characterized by attributes as a high space utilization rate, low power consumption, no radiation, and low electromagnet interference, and thus have been the current market trend.

The TN-type LCDs have been transitioned into the IPS-type (or FFS-type) or VA-type LCDs due to the demands toward the brightness, viewing angle, and response time. While the precision of the LCD is enhanced, the dimension of the pixel has been decreased. As such, the aperture rate is also getting smaller, which may affect the display brightness of the LCDs.

In addition, within conventional LCDs, a storage capacitor is configured within the pixel. Also, the masking lines are configured to shadow the optical leakage occurring at edges of the data lines and the pixel electrodes, which further decrease the aperture rate. Thus, it is needed to overcome the above problems.

### SUMMARY

In one aspect, a backlight module includes: a light guiding plate including at least one light incident surface; a light source unit being arranged close to the light incident surface; and a light conversion unit being fixed between the light source unit and the light incident surface, and the light conversion unit converts light beams emitted from the light source unit to white light beams.

In one aspect, an array substrate includes: a transparent substrate; at least one gate line, at least one data line, and at least one storage electrode line are arranged on the transparent substrate, the gate line and the data line are insulated from each other to define a pixel area, and the storage electrode line is arranged within the pixel area; and at least one switch component arranged at an intersection of the gate line and the data line, the switch component includes a control end, an input end, and an output end, the control end connects to the gate line, the input end connects to the data line, and the output end extends into the pixel area so as to be opposite to the storage electrode line, and the output end and the storage electrode line are insulated from each other.

Wherein the switch component is a thin film transistor (TFT), the control end of the switch component is a gate of the TFT, the input end of the switch component is a source of the TFT, and the output end of the switch component is a drain of the TFT.

Wherein the array substrate further includes a common electrode arranged above the gate line, the data line, and the switch component.

Wherein the array substrate further includes a common electrode arranged above the gate line, the data line, and the switch component.

Wherein the array substrate further includes at least one pixel electrode arranged within the pixel area, wherein the pixel electrode extends toward the output end of the pixel area, and the pixel electrode connects to the output end extending toward the pixel area via a through hole.

Wherein the array substrate further includes at least one pixel electrode arranged within the pixel area, wherein the pixel electrode extends toward the output end of the pixel area, and the pixel electrode connects to the output end extending toward the pixel area via a through hole.

Wherein the array substrate further includes at least one pixel electrode arranged within the pixel area, wherein pixel electrode connects to the output end extending toward the pixel area via a through hole.

Wherein the array substrate further includes at least one pixel electrode arranged within the pixel area, wherein pixel electrode connects to the output end extending toward the pixel area via a through hole.

In another aspect, a manufacturing method of array substrates includes: (A) providing a transparent substrate; (B) forming at least one gate line, at least one gate, and at least one storage electrode line on the transparent substrate, and wherein the gate connects to the gate line; (C) forming at least one data line, at least one source, and at least one drain on the transparent substrate, the gate line and the data line are isolated from each other, and the gate line and the data line intersects with each other to define a pixel area, the storage electrode line is arranged within the pixel area, the source connects to the data line, and the drain extends into the pixel area so as to be opposite to the storage electrode line, and the output end and the storage electrode line are insulated from each other.

Wherein the method further includes: (D) forming at least one common electrode on the gate line, the data line, and the switch component by transparent conductive material, wherein the common electrode, the gate line, and the data line are insulated from the switch component.

Wherein the method further includes: (E) forming at least one pixel electrode within the pixel area by the transparent conductive material, wherein the pixel electrode connects to the drain extending into the pixel area via a through hole.

Wherein the step (D) and the step (E) are executed simultaneously, or the step (E) is executed before the step (D).

In view of the above, the drain extending toward the pixel area and the storage electrode form the storage capacitor, such that a specific storage capacitor may be excluded. In addition, the masking lines at two ends of the data line may be removed, such that the aperture rate and the display brightness may be enhanced.

### BRIEF DESCRIPTION OF THE DRAWINGS

FIG. 1 is a schematic view of the array substrate in accordance with one embodiment.

FIG. 2 is a flowchart illustrating the manufacturing method of the array substrate in accordance with one embodiment.

FIG. 3 is a schematic view of the liquid crystal panel in accordance with one embodiment.

### DETAILED DESCRIPTION OF THE EMBODIMENTS

Embodiments of the invention will now be described more fully hereinafter with reference to the accompanying drawings, in which embodiments of the invention are shown. Various example embodiments will now be described more fully with reference to the accompanying drawings in which some example embodiments are shown. In the drawings, the thicknesses of layers and regions may be exaggerated for clarity.

It can be understood that when a layer or element is referred to or formed on another layer or “on” the substrate, it means that the layer or element may be directly formed on the other layer or substrate, or there is an intermediate layer between the layer or element and the substrate.

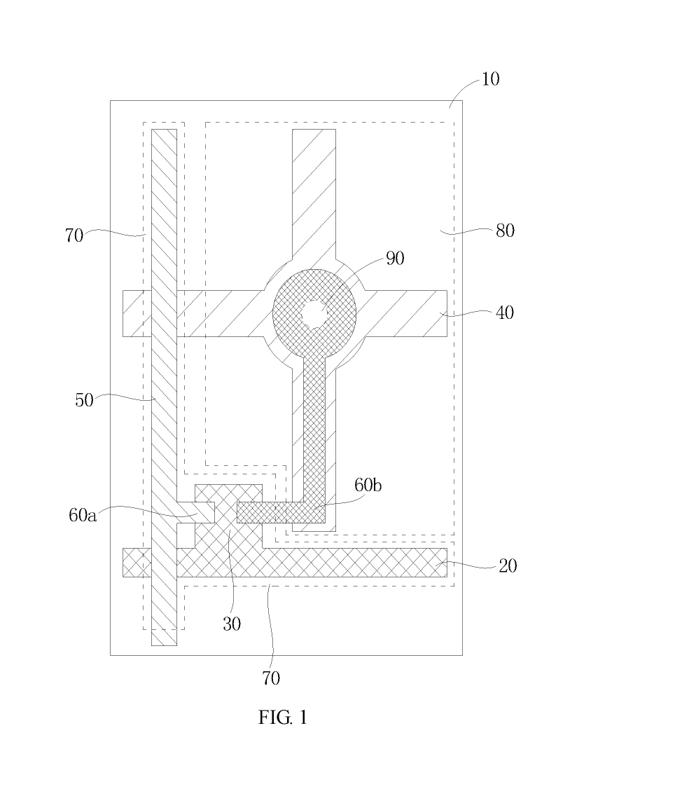

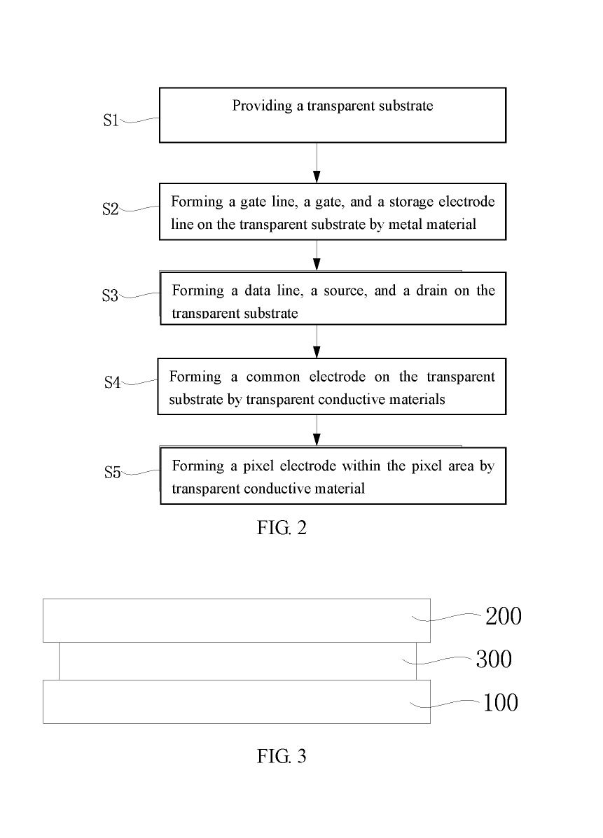

FIG. 1 is a schematic view of the array substrate in accordance with one embodiment. FIG. 2 is a flowchart illustrating the manufacturing method of the array substrate in accordance with one embodiment.

Referring to FIGS. 1 and 2, in step S1, providing a transparent substrate 10. In the embodiment, the transparent substrate 10 may be, but not limited to, a transparent glass substrate or resin substrate.

In step S2, forming a gate line 20, a gate 30, and a storage electrode line 40 on the transparent substrate 10 by metal material. The gate 30 connects with the gate line 20 to receive gate signals from the gate line 20. It can be understood that the storage electrode line 40 is electrically insulated from the gate line 20 and the gate 30. In addition, the metal material may be, but not limited to, chromium or molybdenum.

In step S3, forming a data line 50, a source 60a, and a drain 60b on the transparent substrate 10. The gate 30, the source 60a, and the drain 60b constitute a thin film transistor (TFT). It should be noted that the data line 50, the source 60a, and the drain 60b are not on the same layer with the gate line 20, the gate 30, and the storage electrode line 40. That is, an insulation layer (not shown) is formed between the data line 50, the source 60a, and the drain 60b and the gate line 20, the gate 30, and the storage electrode line 40. In an example, the metal material may be, but not limited to, chromium or molybdenum.

Further, from a top view, the gate line 20 and the data line 50 are insulated from each other, and the gate line 20 intersect with the data line 50 to define a pixel area (A). The storage electrode line 40 is configured within the pixel area (A), and the source 60a connects to the data line 50. The drain 60b extends into the pixel area (A) so as to be opposite to the storage electrode line 40, and the drain 60b is insulated from the storage electrode line 40. In this way, the drain 60b extending toward the pixel area (A) and the storage electrode line 40 form a storage capacitor.

In step S4, forming a common electrode 70 on the transparent substrate 10 by transparent conductive materials, wherein the common electrode 70 is arranged above the gate line 20, the data line 50, and the TFT. In addition, the insulation layer (not shown) is formed between the common electrode 70 and the gate line 20, data line 50, and the TFT. That is, the common electrode 70 is insulated from the gate line 20, the data line 50, and the TFT. In an example, the transparent conductive material may be, but not limited to, ITO. As a thickness of the insulation layer between the common electrode 70 and the data line 50 may be in a range from 2 um to 3 um, and thus the parasitic capacitance between the common electrode 70 and the data line 50 is small, which may only slightly affect the signal delay.

In step S5, forming a pixel electrode 80 within the pixel area (A) by transparent conductive material, wherein the pixel electrode 80 connects to the drain 60b extending toward the pixel area (A) by a through hole 90. In an example, the transparent conductive material may be, but not limited to, ITO.

It is to be noted that, in other embodiments, the steps S5 and S4 may be executed at the same time, or the step S5 may be executed before the step S4.

In addition, the TFT is adopted as a three-end switch component, and wherein a control end of the switch component is a gate of the TFT, an input end of the switch component is a source of the TFT, and the output end of the switch component is a drain of the TFT.

FIG. 3 is a schematic view of the liquid crystal panel in accordance with one embodiment. The liquid crystal panel includes a color filter (CF) substrate 100, an array substrate 200, and a liquid crystal layer 300. The array substrate 200 may be the array substrate in FIG. 1 or the array substrate manufactured by the manufacturing method of FIG. 2.

The CF substrate 100 is opposite to the array substrate 200. In the embodiment, the CF substrate 100 includes RGB photo-resist, black matrixes, and other necessary components. The array substrate 200 includes TFTs, at least one pixel electrode, and other necessary components.

The liquid crystal layer 300 is arranged between the transparent substrate 10 and the array substrate 200. The liquid crystal layer 300 includes a plurality of liquid crystal molecules, wherein the liquid crystal molecules are rotated in accordance with the applied voltage.

In view of the above, the drain extending toward the pixel area and the storage electrode form the storage capacitor, such that a specific storage capacitor may be excluded. In addition, the masking lines at two ends of the data line may be removed, such that the aperture rate and the display brightness may be enhanced.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. An array substrate, comprising:
a transparent substrate;
at least one gate line, at least one data line, and at least one storage electrode line are arranged on the transparent substrate, the gate line and the data line are insulated from each other to define a pixel area, and the storage electrode line is arranged within the pixel area; and
at least one switch component arranged at an intersection of the gate line and the data line, the switch component comprises a control end, an input end, and an output end, the control end connects to the gate line, the input end connects to the data line, and the output end extends into the pixel area so as to be opposite to the storage electrode line, and the output end and the storage electrode line are insulated from each other.

2. The array substrate as claimed in claim 1, wherein the switch component is a thin film transistor (TFT), the control end of the switch component is a gate of the TFT, the input end of the switch component is a source of the TFT, and the output end of the switch component is a drain of the TFT.

3. The array substrate as claimed in claim 1, wherein the array substrate further comprises a common electrode arranged above the gate line, the data line, and the switch component.

4. The array substrate as claimed in claim 2, wherein the array substrate further comprises a common electrode arranged above the gate line, the data line, and the switch component.

5. The array substrate as claimed in claim 1, wherein the array substrate further comprises at least one pixel electrode arranged within the pixel area, wherein the pixel electrode extends toward the output end of the pixel area, and the pixel electrode connects to the output end extending toward the pixel area via a through hole.

6. The array substrate as claimed in claim 2, wherein the array substrate further comprises at least one pixel electrode arranged within the pixel area, wherein the pixel electrode extends toward the output end of the pixel area, and the pixel electrode connects to the output end extending toward the pixel area via a through hole.

7. The array substrate as claimed in claim 3, wherein the array substrate further comprises at least one pixel electrode arranged within the pixel area, wherein pixel electrode connects to the output end extending toward the pixel area via a through hole.

8. The array substrate as claimed in claim 4, wherein the array substrate further comprises at least one pixel electrode arranged within the pixel area, wherein pixel electrode connects to the output end extending toward the pixel area via a through hole.

9. A manufacturing method of array substrates, comprising:
(A) providing a transparent substrate;
(B) forming at least one gate line, at least one gate, and at least one storage electrode line on the transparent substrate, and wherein the gate connects to the gate line;
(C) forming at least one data line, at least one source, and at least one drain on the transparent substrate, the gate line and the data line are isolated from each other, and the gate line and the data line intersects with each other to define a pixel area, the storage electrode line is arranged within the pixel area, the source connects to the data line, and the drain extends into the pixel area so as to be opposite to the storage electrode line, and the output end and the storage electrode line are insulated from each other.

10. The manufacturing method as claimed in claim 9, wherein the method further comprises:
(D) forming at least one common electrode on the gate line, the data line, and the switch component by transparent conductive material, wherein the common electrode, the gate line, and the data line are insulated from the switch component.

11. The manufacturing method as claimed in claim 10, wherein the method further comprises:
(E) forming at least one pixel electrode within the pixel area by the transparent conductive material, wherein the pixel electrode connects to the drain extending into the pixel area via a through hole.

12. The manufacturing method as claimed in claim 11, wherein the step (D) and the step (E) are executed simultaneously, or the step (E) is executed before the step (D).
